(19) United States
(12) Patent Application Publication
(10) Pub. No.: US 2024/0186274 A1
(43) Pub. Date: Jun. 6, 2024

(54) TECHNIQUES FOR THERMAL DISTRIBUTION IN COUPLED SEMICONDUCTOR SYSTEMS

(71) Applicant: Micron Technology, Inc., Boise, ID (US)

(72) Inventors: Amy Rae Griffin, Boise, ID (US); Brent Keeth, Boise, ID (US); Kunal R. Parekh, Boise, ID (US); Eiichi Nakano, Boise, ID (US); James Brian Johnson, Boise, ID (US); Ameen D. Akel, Rancho Cordova, CA (US)

(21) Appl. No.: 18/522,457

(22) Filed: Nov. 29, 2023

Related U.S. Application Data
(60) Provisional application No. 63/429,422, filed on Dec. 1, 2022.

(51) Int. Cl. H01L 23/00; H01L 23/29; H01L 25/065; H10B 80/00

(52) U.S. Cl. CPC H01L 24/08; H01L 23/29; H01L 24/80; H01L 25/0657; H10B 80/00; H01L 2224/08145; H01L 2224/80895; H01L 2224/80896

(57) ABSTRACT

Methods, systems, and devices for thermal distribution techniques in coupled semiconductor systems are described. A semiconductor system may be formed by coupling various semiconductor components with one another, and may also implement a semiconductor material to support a thermal path having a thermal conductivity that is relatively close to a thermal conductivity through the coupled semiconductor components of the semiconductor system. Such a semiconductor material may be located in regions of the semiconductor system that are otherwise unoccupied by functional (e.g., electrically operable) semiconductor components and may, in some examples, be electrically inoperable (e.g., may lack functional circuitry). For implementations in which functional semiconductor components are directly coupled (e.g., by fusion bonding or hybrid bonding techniques), the semiconductor material may also be directly coupled with at least one of the semiconductor components.

### CROSS REFERENCE

The present Application for Patent claims the benefit of and priority to U.S. Provisional Patent Application No. 63/429,422 by Griffin et al., entitled “TECHNIQUES FOR THERMAL DISTRIBUTION IN COUPLED SEMICONDUCTOR SYSTEMS,” filed Dec. 1, 2022, which is assigned to the assignee hereof, and which is expressly incorporated by reference in its entirety herein.

### TECHNICAL FIELD

The following relates to one or more systems for memory, including techniques for thermal distribution in coupled semiconductor systems.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. . Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source. Some memory devices may be implemented as part of a stack of semiconductor dies, and heat transfer associated with operations of the stack of semiconductor dies may be affected by thermal conductivity of the semiconductor dies themselves, of intervening materials such as bonding materials or thermal interface materials, or of other materials or interfaces between the stack of semiconductor dies and an environment around the stack of semiconductor dies.

### BRIEF DESCRIPTION OF THE DRAWINGS

FIG. 1 illustrates an example of a system that supports techniques for thermal distribution in coupled semiconductor systems in accordance with examples as disclosed herein.

FIG. 2 illustrates an example of a semiconductor system that supports techniques for thermal distribution in coupled semiconductor systems in accordance with examples as disclosed herein.

FIG. 3 illustrates an example of a bonding diagram that supports techniques for thermal distribution in coupled semiconductor systems in accordance with examples as disclosed herein.

FIGS. 4A and 4B illustrate examples of semiconductor component layouts that support techniques for thermal distribution in coupled semiconductor systems in accordance with examples as disclosed herein.

FIGS. 5 and 6 illustrate flowcharts showing methods that support techniques for thermal distribution in coupled semiconductor systems in accordance with examples as disclosed herein.

### DETAILED DESCRIPTION

A semiconductor system may be formed by coupling various semiconductor components (e.g., subcomponents, subsystems) with one another, such as coupling one semiconductor die with another semiconductor die (e.g., in accordance with a chip-to-chip (C2C) bonding), coupling a stack of semiconductor dies with another semiconductor die, or coupling respective sets of one or more semiconductor dies with a semiconductor wafer (e.g., in accordance with a chip-to-wafer (C2W) bonding), among other examples. Operations performed by a semiconductor system may generate heat, which may be distributed through the semiconductor system in accordance with various thermal paths of the semiconductor system. In some implementations, an arrangement of materials of a semiconductor system may be associated with a mismatch of thermal conductivities, where some regions of the semiconductor system have a relatively lower thermal conductivity than other regions. For example, some semiconductor systems may include bonding materials or other interface materials between or around the semiconductor components, or one or more regions that lack a material (e.g., air gaps, air interfaces), that have a different thermal conductivity than the semiconductor components themselves, or a different thermal conductivity than a coupling between the semiconductor components (e.g., related to differences in bonding techniques or bonding materials). Additionally, or alternatively, one semiconductor component of the semiconductor system may have a different footprint (e.g., cross-sectional area, as viewed along a stack direction) than another semiconductor component, which also may be associated with a difference in thermal conductivity from one region of the semiconductor system to another. In some examples, a mismatch of thermal conductivities (e.g., along a stack direction, along a thickness direction) in different regions of a semiconductor system may lead to an uneven temperature distribution (e.g., hot spots, which may be related to differences in rejecting generated heat) in the semiconductor system, which may affect the operations performed by the semiconductor system.

In accordance with examples as described herein, a semiconductor system may implement a semiconductor material (e.g., a thermal semiconductor portion, a separately-formed semiconductor portion) to support a thermal path having a thermal conductivity that is relatively close to a thermal conductivity through coupled semiconductor components of the semiconductor system. Such a semiconductor material may be located in regions of the semiconductor system that are otherwise unoccupied by functional semiconductor components and may, in some examples, be electrically inoperable (e.g., may lack functional circuitry). For example, when a first semiconductor component has a footprint that is larger than a second semiconductor component, a thermal conductivity in a first region of the semiconductor system (e.g., through the first and second semiconductor components) may be approximated by coupling the semiconductor material with the first semiconductor component in a second region that is not occupied by the second semiconductor component (e.g., associated with a thermal conductivity through the first semiconductor component and the semiconductor material). In some examples, such as when the first and second semiconductor components are directly coupled (e.g., without a bonding material, by fusion bonding or hybrid bonding), the semiconductor material may also be directly coupled with the first semiconductor component (e.g., by fusion bonding), to improve the similarity of thermal conductivities (e.g., along the stack direction) in the different regions. By supporting a more-uniform thermal conductivity in different regions of a semiconductor system, such a semiconductor material portion may be implemented to reduce hot spots in the semiconductor system and support more-uniform operating characteristics in the different regions of the semiconductor system.

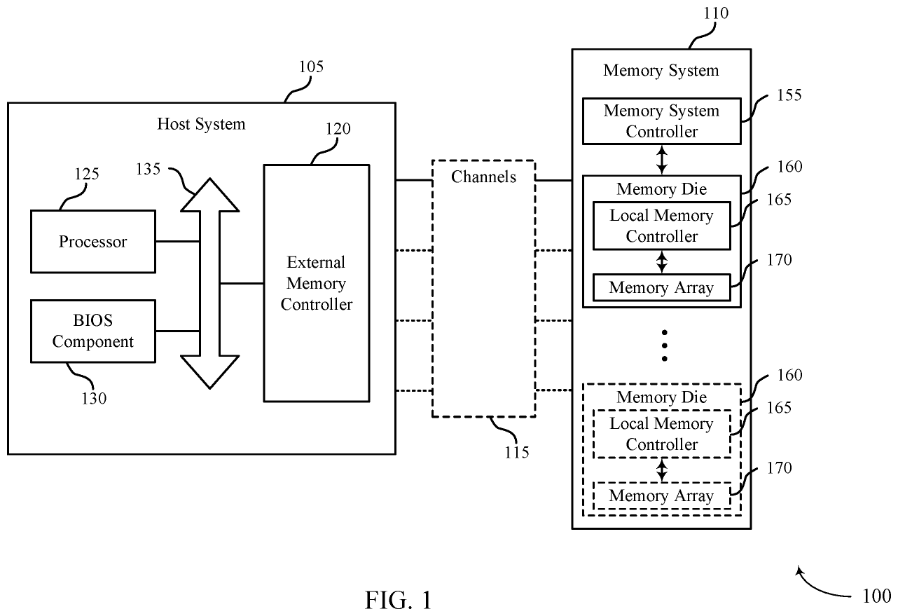

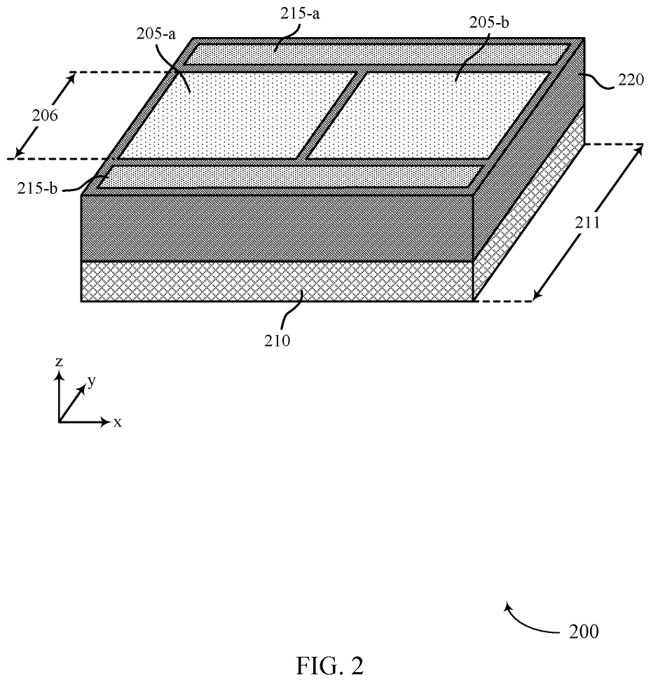

Features of the disclosure are initially illustrated and described in the context of a system with reference to FIG. 1. Features of the disclosure are illustrated and described in the context of a semiconductor system, a bonding diagram, layouts, and flowcharts with reference to FIGS. 2 through 6.

FIG. 1 illustrates an example of a system 100 that supports techniques for coupled host and memory dies in accordance with examples as disclosed herein. The system 100 may include portions of an electronic device, such as a computing device, a mobile computing device, a wireless communications device, a graphics processing device, a vehicle, or other systems. The system 100 includes a host system 105, a memory system 110, and one or more channels 115 coupling the host system 105 with the memory system 110 (e.g., to provide a communicative coupling). The system 100 may include one or more memory systems 110, but aspects of the one or more memory systems 110 may be described in the context of a single memory system 110.

The host system 105 may be an example of a processor (e.g., circuitry, processing circuitry, a processing component) that uses memory to execute processes, such as a processing system of a computing device, a mobile computing device, a wireless communications device, a graphics processing device, a wearable device, an internet-connected device, a vehicle controller, a system on a chip (SoC), or other stationary or portable electronic device, among other examples. The host system 105 may include one or more of an external memory controller 120, a processor 125, a basic input/output system (BIOS) component 130, or other components (e.g., a peripheral component, an input/output controller, not shown). The components of the host system 105 may be coupled with one another using a bus 135.

An external memory controller 120 may be configured to enable communication of information (e.g., data, commands, control information, configuration information) between components of the system 100 (e.g., between components of the host system 105, such as the processor 125, and the memory system 110). An external memory controller 120 may process (e.g., convert, translate) communications exchanged between the host system 105 and the memory system 110. In some examples, an external memory controller 120, or other component of the system 100, or associated functions described herein, may be implemented by or be part of the processor 125. For example, an external memory controller 120 may be hardware, firmware, or software (e.g., instructions), or some combination thereof implemented by a processor 125 or other component of the system 100 or the host system 105. Although an external memory controller 120 is illustrated outside the memory system 110, in some examples, an external memory controller 120, or its functions described herein, may be implemented by one or more components of a memory system 110 (e.g., a memory system controller 155, a local memory controller 165) or vice versa. In various examples, the host system 105 or an external memory controller 120 may be referred to as a host.

A processor 125 may be operable to provide functionality (e.g., control functionality) for the system 100 or the host system 105. A processor 125 may be a general-purpose processor, a digital signal processor (DSP), an application-specific integrated circuit (ASIC), a field-programmable gate array (FPGA) or other programmable logic device, discrete gate or transistor logic, discrete hardware components, or any combination thereof. In some examples, a processor 125 may be an example of a central processing unit (CPU), a graphics processing unit (GPU), a general purpose GPU (GPGPU), or a system on a chip (SoC), among other examples.

In some examples, the system 100 or the host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

The memory system 110 may be a component of the system 100 that is operable to provide physical memory locations (e.g., addresses) that may be used or referenced by the system 100. The memory system 110 may include a memory system controller 155 and one or more memory dies 160 (e.g., memory chips) to support a capacity for data storage. The memory system 110 may be configurable to work with one or more different types of host systems 105, and may respond to and execute commands provided by the host system 105 (e.g., via an external memory controller 120). For example, the memory system 110 (e.g., a memory system controller 155) may receive a write command indicating that the memory system 110 is to store data received from the host system 105, or receive a read command indicating that the memory system 110 is to provide data stored in a memory die 160 to the host system 105, or receive a refresh command indicating that the memory system 110 is to refresh data stored in a memory die 160, among other types of commands and operations.

A memory system controller 155 may include components (e.g., circuitry, logic) operable to control operations of the memory system 110. A memory system controller 155 may include hardware, firmware, or instructions that enable the memory system 110 to perform various operations, and may be operable to receive, transmit, or execute commands, data, or control information related to operations of the memory system 110. A memory system controller 155 may be operable to communicate with one or more of an external memory controller 120, one or more memory dies 160, or a processor 125. In some examples, a memory system controller 155 may control operations of the memory system 110 in cooperation with a local memory controller 165 of a memory die 160.

Each memory die 160 may include a local memory controller 165 and a memory array 170. A memory array 170 may be a collection of memory cells, with each memory cell being operable to store one or more bits of data. A memory die 160 may include a two-dimensional (2D) array of memory cells, or a three-dimensional (3D) array of memory cells. In some examples, a 2D memory die 160 may include a single memory array 170. In some examples, a 3D memory die 160 may include two or more memory arrays 170, which may be stacked or positioned beside one another (e.g., relative to a substrate).

A local memory controller 165 may include components (e.g., circuitry, logic) operable to control operations of a memory die 160. In some examples, a local memory controller 165 may be operable to communicate (e.g., receive or transmit data or commands or both) with a memory system controller 155. In some examples, a memory system 110 may not include a memory system controller 155, and a local memory controller 165 or an external memory controller 120 may perform various functions described herein. As such, a local memory controller 165 may be operable to communicate with a memory system controller 155, with other local memory controllers 165, or directly with an external memory controller 120, or a processor 125, or any combination thereof. Examples of components that may be included in a memory system controller 155 or a local memory controller 165 or both may include receivers for receiving signals (e.g., from the external memory controller 120), transmitters for transmitting signals (e.g., to the external memory controller 120), decoders for decoding or demodulating received signals, encoders for encoding or modulating signals to be transmitted, sense components for sensing states of memory cells of a memory array 170, write components for writing states to memory cells of a memory array 170, or various other components operable for supporting described operations of a memory system 110.

A host system 105 (e.g., an external memory controller 120) and a memory system 110 (e.g., a memory system controller 155) may communicate information (e.g., data, commands, control information, configuration information) using one or more channels 115. Each channel 115 may be an example of a transmission medium that carries information, and each channel 115 may include one or more signal paths (e.g., a transmission medium, an electrical conductor, an electrically conductive path) between terminals associated with the components of the system 100. For example, a channel 115 may be associated with a first terminal (e.g., including one or more pins, including one or more pads) at the host system 105 and a second terminal at the memory system 110. A terminal may be an example of an electrically conductive input or output point of a device of the system 100, and a terminal may be operable to act as part of a channel 115.

In some examples, a channel 115 (e.g., associated signal paths and terminals) may be dedicated to communicating one or more types of information. For example, the channels 115 may include one or more command and address channels, one or more clock signal channels, one or more data channels, among other channels or combinations thereof. In some examples, signaling may be communicated over the channels 115 using single data rate (SDR) signaling or double data rate (DDR) signaling. In SDR signaling, one modulation symbol (e.g., signal level) of a signal may be registered for each clock cycle (e.g., on a rising or falling edge of a clock signal). In DDR signaling, two modulation symbols of a signal may be registered for each clock cycle (e.g., on both a rising edge and a falling edge of a clock signal). In some examples, at least a subset of channels 115 may be configured in accordance with a protocol (e.g., a logical protocol, a communications protocol, an operational protocol), which may support operations of and interactions between a host system 105 and a memory system 110. For example, the host system 105, the memory system 110, at least a subset of the channels 115, or a combination thereof may be configured in accordance with a high bandwidth memory (HBM) protocol or a protocol in accordance with another memory standard.

In some examples, aspects of the system 100 may be implemented in respective semiconductor components (e.g., a die, a stack of dies, a wafer), which may be coupled together to form a semiconductor system (e.g., a coupled semiconductor system). The semiconductor system may implement a semiconductor material (e.g., a thermal semiconductor portion, an electrically inoperative semiconductor material) in regions of the semiconductor system that are otherwise unoccupied by functional semiconductor components, which may support a thermal path having a thermal conductivity that is relatively close to a thermal conductivity through the coupled functional semiconductor components. By supporting a more-uniform thermal conductivity in different regions of a semiconductor system, such a semiconductor material portion may be implemented to reduce hot spots in the semiconductor system and support more uniform operating characteristics in the different regions of the semiconductor system.

FIG. 2 illustrates an example of a semiconductor system 200 (e.g., a semiconductor assembly) that supports techniques for thermal distribution in coupled semiconductor systems in accordance with examples as disclosed herein. Aspects of the semiconductor system 200 may be described with reference to an x-direction, a y-direction, and a z-direction of the illustrated coordinate system, where the z-direction may be illustrative of a direction (e.g., a vertical direction, a thickness direction, a stack direction) that is orthogonal to or otherwise relative to a surface in an xy-plane (e.g., a substrate plane, a coupling plane) of the semiconductor system 200. Although FIG. 2 illustrates examples of relative dimensions and quantities of various features, aspects of the semiconductor system 200 may be implemented with other relative dimensions or quantities of such features in accordance with examples as disclosed herein.

The semiconductor system 200 includes semiconductor components 205 (e.g., semiconductor components 205-a and 205-b), a semiconductor component 210, and semiconductor components 215 (e.g., semiconductor components 215-a and 215-b). Although FIG. 2 illustrates an example of a semiconductor system 200 that includes two semiconductor components 205 and two semiconductor components 215, a semiconductor system 200 in accordance with the described techniques may include any quantity of one or more semiconductor components 205, and any quantity of one or more semiconductor components 215. Each of the semiconductor components 205 and each of the semiconductor components 215 may be coupled with (e.g., physically coupled with, bonded with) the semiconductor component 210. In some examples, the semiconductor component 210 may be a semiconductor wafer or a portion thereof (e.g., a semiconductor die cut from a semiconductor wafer), and each semiconductor component 205 may be a single semiconductor die, or may be a stack of multiple semiconductor dies. The semiconductor component 210 and the semiconductor components 205 may each include electrically operable circuitry (e.g., functional circuitry), which may be supported by a respective communicative coupling (e.g., electrical coupling) between at least the semiconductor component 210 and each semiconductor component 205 and, in some examples, a communicative coupling with a component outside the semiconductor system 200 (e.g., an interfacing component, a user interface).

In some implementations, the semiconductor system 200 may include at least some features of a memory system 110. For example, each semiconductor component 205 may include a respective set of one or more memory arrays (e.g., one or more memory arrays 170, of one or more respective semiconductor dies), and the semiconductor component 205, or the semiconductor component 210, or a combination thereof may include at least a portion of the circuitry for accessing the respective set of memory arrays (e.g., aspects of a local memory controller 165, aspects of a memory system controller 155). In some implementations, the semiconductor component 210 may include at least some control circuitry for accessing respective memory arrays of at least one semiconductor component 205. In some implementations, the semiconductor component 210 may also include at least some features of a host (e.g., of a host system 105), such including aspects of a host processor (e.g., a processor 125), or an external memory controller 120, or a combination thereof.

Operations performed by the semiconductor system 200 (e.g., operations of the semiconductor component 210, operations of the semiconductor components 205) may generate heat, which may be distributed through the semiconductor system 200 in accordance with various thermal paths. However, in some implementations, a semiconductor component 210 may be associated with a larger footprint (e.g., a larger cross-section as viewed along the z-direction, a larger dimension along one or more directions in an xy-plane, such as a ‘porch’ region) than a semiconductor component 205, or a pattern of multiple semiconductor components 205, coupled with the semiconductor component 210. For example, as illustrated, the semiconductor component 210 may be associated with a dimension 211 along the y-direction that is greater than a dimension 206 along the y-direction that is associated with the semiconductor components 205.

To improve the uniformity (e.g., along an xy-plane) of thermal conductivity through the semiconductor system (e.g., along the z-direction), and reduce the likelihood of hot spots (e.g., in locations of the semiconductor component 210 that are not coupled with a semiconductor component 205), the semiconductor system 200 may include semiconductor components 215 (e.g., thermal path components, thermal semiconductor components), which may be coupled with the semiconductor component 210 in regions that are not coupled with the semiconductor components 205. A semiconductor component 215 may include (e.g., be formed from) a material that provides a thermal conductivity that is equal to or similar to the thermal conductivity of the semiconductor components 205 (e.g., along at least the z-direction), such as silicon material or another semiconductor material. In some implementations, a semiconductor component 215 may be implemented with a height (e.g., along the z-direction, a thickness, one or more extents) that is similar to (e.g., the same as) a height of one or more semiconductor components 205, or with a height that is different than (e.g., shorter than, taller than) one or more semiconductor components 205 (e.g., to compensate for differences in thermal conductivity between a material of a semiconductor component 215 and a material of a semiconductor component 205).

Because the semiconductor components 215 are implemented to provide a thermal path (e.g., rather than an electrical circuit functionality), the semiconductor components 215 may not include electrically operable circuitry. Thus, the semiconductor components 215 may implement a lower-grade semiconductor material than a semiconductor component 210 or a semiconductor component 205. For example, a semiconductor component 210, or a semiconductor component 205, or both may implement at least some crystalline semiconductor (e.g., from a crystalline silicon wafer) to support relatively high-performance circuitry (e.g., transistors formed at least in part from doped portions of a crystalline semiconductor substrate), whereas the semiconductor components 215 may be formed from a polycrystalline semiconductor (e.g., from a block or otherwise physically contiguous or monolithic piece of polycrystalline silicon or other semiconductor). In some examples. selecting a material for the semiconductor components 215 that is similar to a material of the semiconductor components 205 may support other aspects of relative uniformity between portions of the semiconductor system, such as a uniformity in bonding characteristics, uniformity in thermal expansion characteristics (e.g., relatively uniform coefficients of thermal expansion (CTE)), or uniformity in strength or stiffness characteristics, among other examples or combinations thereof.

In some examples, the semiconductor components 205 may be directly coupled with the semiconductor component 210 (e.g., without a separate bonding material). For example, to support a communicative coupling, a coupling between the semiconductor components 205 and the semiconductor component 210 may include a fusion between respective conductive portions (e.g., electrically conductive portions, conductive contacts) of the semiconductor components 205 and the semiconductor component 210. In some examples (e.g., in accordance with a hybrid bonding), a coupling between the semiconductor components 205 and the semiconductor component 210 may also include a fusion between respective dielectric portions (e.g., oxide portions, nitride portions, carbide portions, oxide-nitride portions, carbide-nitride portions, or other semiconductor conversions or depositions) of the semiconductor components 205 and the semiconductor component 210.

In such examples, to support a relatively uniform thermal conductivity across the semiconductor system 200, the semiconductor components 215 may also be directly coupled with the semiconductor component 210 (e.g., without a separate bonding material). In some examples, a direct coupling between a semiconductor component 215 and the semiconductor component 210 may include a fusion between respective dielectric portions (e.g., oxide portions, nitride portions, carbide portions, oxide-nitride portions, carbide-nitride portions, or other semiconductor conversions or depositions) of the semiconductor components 215 and the semiconductor component 210. In some examples, a coupling between the semiconductor components 215 and the semiconductor component 210 may include a fusion between respective conductive portions (e.g., electrically conductive portions), or material portions of other types, at surfaces of the semiconductor components 215 and the semiconductor component 210, but such a coupling may be configured as a non-communicative coupling (e.g., a non-communicative and thermally conductive coupling). Thus, in accordance with these and other examples, a thermal conductivity through the semiconductor component 210 and a semiconductor component 215 may be similar to a thermal conductivity through semiconductor component 210 and a semiconductor component 205, which may support a more balanced temperature distribution along an xy-plane (e.g., to reduce a likelihood of hot spots in at least the semiconductor component 210), which may support more-uniform operating characteristics in different regions of the semiconductor system 200.

In some cases, the semiconductor system 200 may also include a material 220, which may be a mold compound, a thermal interface material (TIM), or an organic compound located around, between, or on top of semiconductor components 205 and semiconductor components 215. The material 220 may be deposited onto the semiconductor system 200 after coupling the semiconductor components 205 and the semiconductor components 215 with the semiconductor component 210. For example, a material 220 may be formed in recesses between the semiconductor components 205 and the semiconductor components 215 and around the semiconductor components 205 and the semiconductor components 215 (e.g., without being located between the semiconductor component 210 and the semiconductor components 205 and semiconductor components 215). In some examples, a top surface, a bottom surface, or both (e.g., along the z-direction) of the semiconductor system 200 may be configured for coupling with a heat sink, which may include a coupling via a TIM (e.g., a thermal paste), which may involve a planarization or other preparation operation along interfacing surfaces of the semiconductor components 205 and semiconductor components 215.

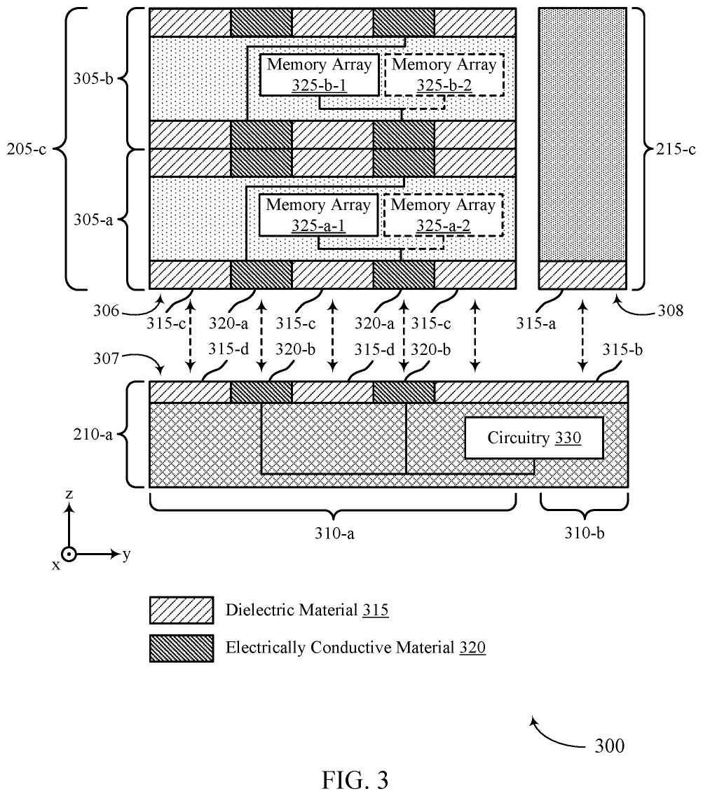

FIG. 3 illustrates an example of a bonding diagram 300) that supports techniques for thermal distribution in coupled semiconductor systems in accordance with examples as disclosed herein. Aspects of the bonding diagram 300 may be described with reference to an x-direction, a y-direction, and a z-direction of the illustrated coordinate system, which may be the same as or similar to the directions of the coordinate system described with reference to FIG. 2. The bonding diagram 300 may illustrate a cross-sectional view of a coupling for a semiconductor system (e.g., including a semiconductor component 205-c, a semiconductor component 210-a, and a semiconductor component 215-c), which may include features described with reference to the semiconductor system 200 of FIG. 2. In some examples, a thickness (e.g., along the z-direction) of the semiconductor component 215-c may be similar to (e.g., the same as, within a manufacturing tolerance of) a thickness of the semiconductor component 205-c.

Although FIG. 3 illustrates examples of relative dimensions and quantities of various features, aspects of the bonding diagram 300 may be implemented with other relative dimensions or quantities of such features in accordance with examples as disclosed herein.

In the example of bonding diagram 300, the semiconductor component 205-c includes multiple semiconductor dies 305 (e.g., semiconductor dies 305-a and 305-b, memory dies), though a semiconductor system formed in accordance with the bonding diagram 300 may include any quantity of one or more semiconductor dies 305 in a semiconductor component 205. Each semiconductor die 305 may include a respective set of one or more memory arrays 325 (e.g., memory arrays 325-a-1 and 325-a-2 of the semiconductor die 305-a, memory arrays 325-b-1 and 325-b-2 of the semiconductor die 305-b), which may be examples of a memory array 170. The semiconductor component 210-a may include circuitry 330, which may include at least a portion of circuitry (e.g., control circuitry) configured for accessing the memory arrays 325. For example, the circuitry 330 may include at least a portion of a local memory controller 165, or a memory system controller 155, or a combination thereof. In some examples, the semiconductor dies 305 may also include at least a portion of circuitry (e.g., a different portion than included in the circuitry 330) configured for accessing the respective memory arrays 325, or such circuitry may be considered to be included within in the illustrative boundaries of memory arrays 325. In some examples, the circuitry 330 may also include at least some features of a host (e.g., of a host system 105), such including aspects of a host processor (e.g., a processor 125), or an external memory controller 120, or a combination thereof.

The bonding diagram 300 illustrates aspects of the semiconductor component 205-c and the semiconductor component 215-c being coupled with the semiconductor component 210-a. For example, a surface 306 of the semiconductor component 205-c may be coupled with a portion of a surface 307 of the semiconductor component 210-a (e.g., a portion 310-a along the y-direction). Coupling the semiconductor component 205-c with the semiconductor component 210-a may form a communicative coupling between at least the memory arrays 325 of the semiconductor component 205-c and the circuitry 330 of the semiconductor component 210-a (e.g., via portions of an electrically conductive material 320) at the surfaces 306 and 307, which each may be illustrative of any quantity of one or more electrically conductive contacts associated with respective signal paths), such that the circuitry 330 may be operable to access the one or more memory arrays 325. In some examples, such a communicative coupling may also be supported via electrically conductive material 320 at interfacing surfaces of the semiconductor dies 305 that are coupled in a stack (e.g., to form the semiconductor component 205-c as a stack of semiconductor dies). Further, a surface 308 of the semiconductor component 215-c may be coupled with a portion of the surface 307 of the semiconductor component 210-a (e.g., a portion 310-b along the y-direction. However, the coupling of the semiconductor component 215 with the semiconductor component 210-a may not form a communicative coupling (e.g., because the semiconductor component 215-c may lack functional circuitry).

In some examples, a coupling between the semiconductor component 215-c and the semiconductor component 210-a may be provided by a fusion bonding, which may include fusing a dielectric material 315-a at the surface 308 with a dielectric material 315-b at the surface 307. The dielectric material 315-a and the dielectric material 315-b may be semiconductor oxide materials (e.g., an oxide of silicon), semiconductor nitride materials (e.g., a nitride of silicon), semiconductor carbide materials (e.g., a carbide of silicon), semiconductor carbon-nitride materials, or any combination thereof (e.g., an oxide-nitride of silicon, a carbon-nitride of silicon). The dielectric material 315-a and the dielectric material 315-b may be the same material or different materials.

In some examples, a coupling between the semiconductor component 205-c and the semiconductor component 210-a may be provided by a hybrid bonding, which may include fusing an electrically conductive material 320-a at the surface 306 with an electrically conductive material 320-b at the surface 307. The electrically conductive material 320-a and the electrically conductive material 320-b may be the same material or different materials, and may each be associated with one or more contacts that support a communicative coupling between the memory arrays 325 and the circuitry 330. In some implementations, the hybrid bonding may also include fusing a dielectric material 315-c at the surface 306 with a dielectric material 315-d at the surface 307. The dielectric material 315-c and the dielectric material 315-d may be semiconductor oxide materials (e.g., an oxide of silicon), semiconductor nitride materials (e.g., a nitride of silicon), semiconductor carbide materials, (e.g., a carbide of silicon), or any combination thereof (e.g., an oxide-nitride of silicon, a carbon-nitride of silicon). The dielectric material 315-c and the dielectric material 315-d may be the same material or different materials. In some examples, the dielectric material 315-d may be contiguous with (e.g., the same material as) the dielectric material 315-b (e.g., from the portion 310-a to the portion 310-b).

In some implementations, one or more of the dielectric materials 315 may be formed at respective surfaces of a semiconductor component (e.g., the semiconductor components 205-c, the semiconductor component 210-a, the semiconductor component 215-c) by oxidizing, nitriding, or otherwise converting a material (e.g., a semiconductor material) at the respective surfaces of the semiconductor component. For example, the dielectric material 315-a may be formed by oxidizing, nitriding, or carbonizing a semiconductor material (e.g., a polycrystalline semiconductor) of the semiconductor component 215-c, or the dielectric material 315-b may be formed by oxidizing or nitriding a semiconductor material (e.g., a crystalline semiconductor) of the semiconductor component 210-a, and so on. Additionally, or alternatively, one or more of the dielectric materials 315 may be formed at respective surfaces of the semiconductor components by depositing the respective dielectric material 315 on the surface of the semiconductor component. For example, a semiconductor oxide, nitride, carbide, oxide-nitride, carbon-nitride, or other material may be deposited on at least the surface 308 of the semiconductor component 215 to form the dielectric material 315-a, and so on. Although illustrated along certain surfaces of the respective semiconductor components (e.g., dielectric material 315-a being on the surface 308 of the semiconductor component 215-c), a dielectric material 315 may be formed on multiple surfaces of (e.g., may enclose) a body of the respective semiconductor component.

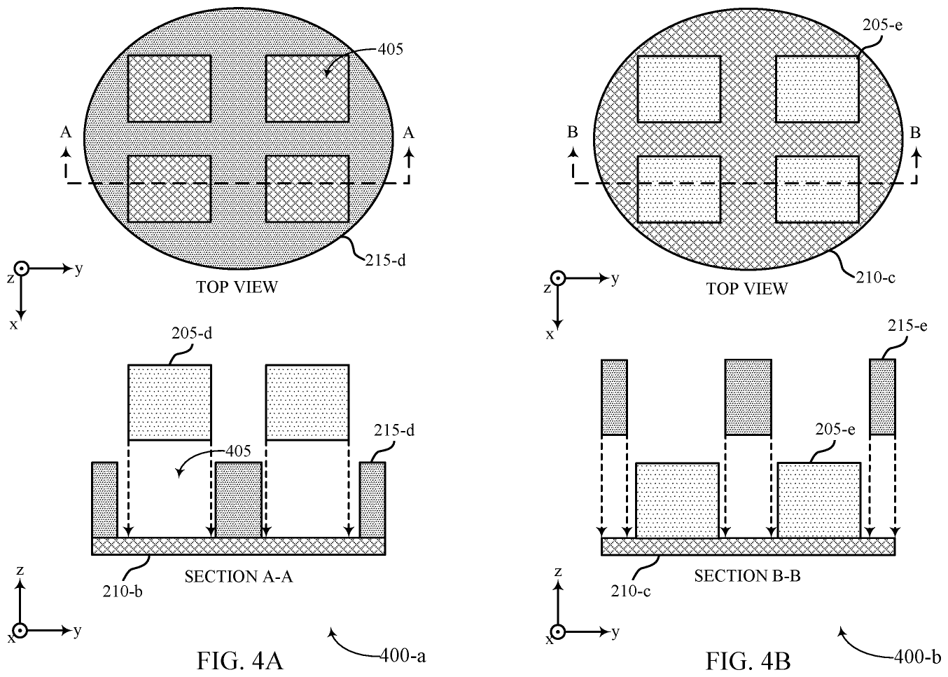

FIGS. 4A and 4B illustrate examples of semiconductor component layouts 400-a and 400-b that support techniques for thermal distribution in coupled semiconductor systems in accordance with examples as disclosed herein. The semiconductor component layouts 400-a and 400-b may illustrate aspects of implementing a semiconductor system 200 or bonding diagram 300. For illustrative purposes, aspects of the semiconductor component layouts 400-a and 400-b may be described with reference to an x-direction, a y-direction, and a z-direction of the illustrated coordinate systems, which may be the same as or similar to the directions of the coordinate systems described with reference to FIG. 2, or FIG. 3, or both. For example, each the semiconductor component layouts 400-a and 400-b may be illustrated with a respective top view and cross sectional view of semiconductor component formations. Although the semiconductor component layouts 400-a and 400-b may illustrate examples of relative dimensions and quantities of various features, aspects of the semiconductor component layouts 400-a and 400-b may be implemented with other relative dimensions or quantities of such features in accordance with examples as disclosed herein.

The semiconductor component layout 400-a may illustrate a coupling (e.g., a depositing) of multiple semiconductor components 205-d onto a semiconductor component 210-b, which may be performed after a semiconductor component 215-d is coupled with the semiconductor component 210-b. For example, the semiconductor component 215-d may be formed with a pattern of openings 405 (e.g., through the semiconductor component 215-d along the z-direction) and deposited onto (e.g., coupled with) the semiconductor component 210-b. In some implementations, the semiconductor component 215-d may have common extents (e.g., in an xy-plane) as the semiconductor component 210-b. The openings 405 may provide locations for the semiconductor components 205-d to be deposited through to the semiconductor component 210-b for coupling the semiconductor components 205-d with the semiconductor component 210-b.

The semiconductor component layout 400-b may illustrate a coupling of a one or more semiconductor components 215-e onto a semiconductor component 210-c, which may be performed after multiple semiconductor components 205-e are coupled with the semiconductor component 210-c. For example, at least a portion of a semiconductor component 215-e may be deposited between respective ones of the semiconductor components 205-e. In various examples, such techniques may be implemented with a single (e.g., contiguous) semiconductor component 215-e, or may be implemented with a set of multiple semiconductor components 215-e (e.g., multiple segments of thermal semiconductor).

In some implementations, the semiconductor component layout 400-a or the semiconductor component layout 400-b may be subdivided into multiple semiconductor systems (e.g., multiple semiconductor assemblies, after respective coupling operations). For example, one or more semiconductor assemblies each including a semiconductor component 205, a portion of a semiconductor component 210, and a portion of a semiconductor component 215 may be formed based at least in part on a separation (e.g., a cut) through the semiconductor component 210 and at least one semiconductor component 215 (e.g., separating the semiconductor component 210 and one or more semiconductor components 215 into separate portions).

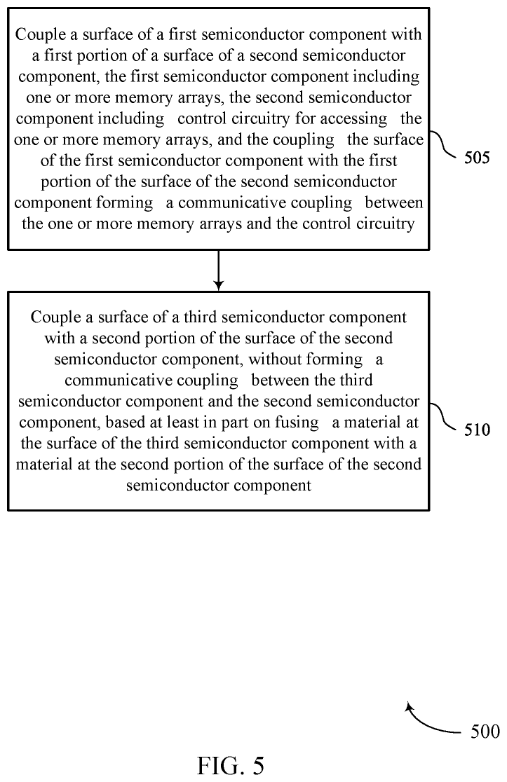

FIG. 5 illustrates a flowchart showing a method 500 that supports techniques for thermal distribution in coupled semiconductor systems in accordance with examples as disclosed herein. The operations of method 500 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 505, the method may include coupling a surface of a first semiconductor component with a first portion of a surface of a second semiconductor component, the first semiconductor component including one or more memory arrays, the second semiconductor component including control circuitry for accessing the one or more memory arrays, and the coupling the surface of the first semiconductor component with the first portion of the surface of the second semiconductor component forming a communicative coupling between the one or more memory arrays and the control circuitry.

At 510, the method may include coupling a surface of a third semiconductor component with a second portion of the surface of the second semiconductor component, without forming a communicative coupling between the third semiconductor component and the second semiconductor component, based at least in part on fusing a first material at the surface of the third semiconductor component with a second material at the second portion of the surface of the second semiconductor component.

In some examples, an apparatus (e.g., a manufacturing system) as described herein may perform a method or methods, such as the method 500. The apparatus may include features (e.g., circuitry, logic, one or more controllers, or other functional elements), or instructions (e.g., a non-transitory computer-readable medium storing instructions executable by one or more controllers to control one or more functional elements of the manufacturing system), or any other means or combination thereof for performing the following aspects of the present disclosure:

Aspect 1: A method or apparatus including operations, features, instructions, or any other means or combination thereof for coupling a surface of a first semiconductor component with a first portion of a surface of a second semiconductor component, the first semiconductor component including one or more memory arrays, the second semiconductor component including control circuitry for accessing the one or more memory arrays, and the coupling the surface of the first semiconductor component with the first portion of the surface of the second semiconductor component forming a communicative coupling between the one or more memory arrays and the control circuitry and coupling a surface of a third semiconductor component with a second portion of the surface of the second semiconductor component, without forming a communicative coupling between the third semiconductor component and the second semiconductor component, based at least in part on fusing a first material at the surface of the third semiconductor component with a second material at the second portion of the surface of the second semiconductor component.

Aspect 2: The method or apparatus of aspect 1, where coupling the surface of the first semiconductor component with the first portion of the surface of the second semiconductor component includes operations, features, instructions, or any other means or combination thereof for fusing one or more portions of a first electrically conductive material at the surface of the first semiconductor component with one or more portions of a second electrically conductive material at the first portion of the surface of the second semiconductor component.

Aspect 3: The method or apparatus of aspect 2, where coupling the surface of the first semiconductor component with the first portion of the surface of the second semiconductor component includes operations, features, instructions, or any other means or combination thereof for fusing one or more portions of a first dielectric material at the surface of the first semiconductor component with one or more portions of a second dielectric material at the first portion of the surface of the second semiconductor component.

Aspect 4: The method or apparatus of aspect 3, where at least a portion of the second material and at least a portion of the second dielectric material are contiguous at the surface of the second semiconductor component.

Aspect 5: The method or apparatus of any of aspects 1 through 4, further including operations, features, instructions, or any other means or combination thereof for forming the first material at the surface of the third semiconductor component based at least in part on oxidizing, nitriding, or carbonizing a semiconductor portion of the third semiconductor component, or a combination thereof.

Aspect 6: The method or apparatus of any of aspects 1 through 5, further including operations, features, instructions, or any other means or combination thereof for forming the first material at the surface of the third semiconductor component based at least in part on depositing a semiconductor oxide material, a semiconductor nitride material, a semiconductor carbide material, or a combination thereof on the surface of the third semiconductor component.

Aspect 7: The method or apparatus of any of aspects 1 through 6, further including operations, features, instructions, or any other means or combination thereof for forming a mold compound adjacent to the first semiconductor component, adjacent to the third semiconductor component, or between the first semiconductor component and the third semiconductor component, or a combination thereof.

Aspect 8: The method or apparatus of any of aspects 1 through 7, further including operations, features, instructions, or any other means or combination thereof for depositing, after coupling the third semiconductor component with the second portion of the surface of the second semiconductor component, the first semiconductor component in an opening through the third semiconductor component and coupling the surface of the first semiconductor component with the first portion of the surface of the second semiconductor component with the first semiconductor component in the opening.

Aspect 9: The method or apparatus of any of aspects 1 through 8, where coupling the surface of the third semiconductor component with the second portion of the surface of the second semiconductor component includes operations, features, instructions, or any other means or combination thereof for depositing the third semiconductor component between a set of multiple first semiconductor components after coupling the set of multiple first semiconductor components with the second semiconductor component.

Aspect 10: The method or apparatus of any of aspects 1 through 9, where the first semiconductor component includes a first semiconductor die including a first subset of the one or more memory arrays and a second semiconductor die, coupled with the first semiconductor die, including a second subset of the one or more memory arrays.

Aspect 11: The method or apparatus of any of aspects 1 through 10, further including operations, features, instructions, or any other means or combination thereof forming a semiconductor assembly including the first semiconductor component, a portion of the second semiconductor component, and a portion of the third semiconductor component based at least in part on a separation through the second semiconductor component and the third semiconductor component.

Aspect 12: The method or apparatus of any of aspects 1 through 11, where the second semiconductor component includes a semiconductor wafer configured for coupling with a plurality of first semiconductor components.

Aspect 13: The method or apparatus of any of aspects 1 through 12, where the third semiconductor component is formed without circuitry.

Aspect 14: The method or apparatus of any of aspects 1 through 13, where the first material is formed over a polycrystalline silicon portion of the third semiconductor component.

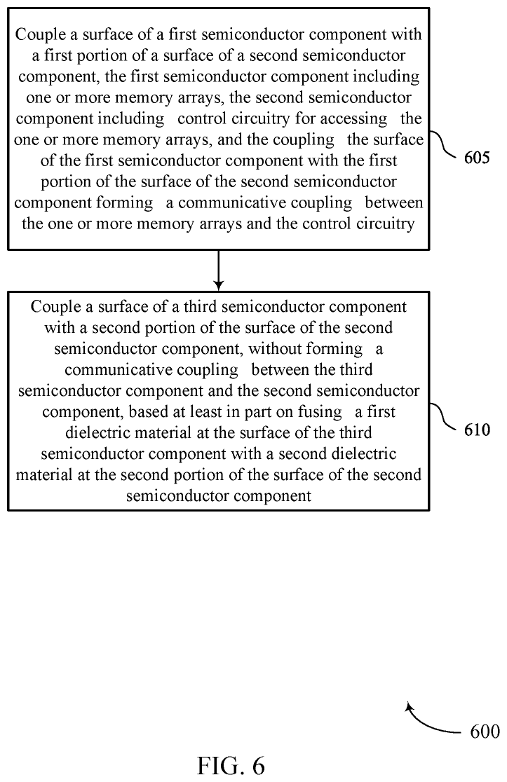

FIG. 6 illustrates a flowchart showing a method 600 that supports techniques for thermal distribution in coupled semiconductor systems in accordance with examples as disclosed herein. The operations of method 600 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 605, the method may include coupling a surface of a first semiconductor component with a first portion of a surface of a second semiconductor component, the first semiconductor component including one or more memory arrays, the second semiconductor component including control circuitry for accessing the one or more memory arrays, and the coupling the surface of the first semiconductor component with the first portion of the surface of the second semiconductor component forming a communicative coupling between the one or more memory arrays and the control circuitry.

At 610, the method may include coupling a surface of a third semiconductor component with a second portion of the surface of the second semiconductor component, without forming a communicative coupling between the third semiconductor component and the second semiconductor component, based at least in part on fusing a first dielectric material at the surface of the third semiconductor component with a second dielectric material at the second portion of the surface of the second semiconductor component.

In some examples, an apparatus (e.g., a manufacturing system) as described herein may perform a method or methods, such as the method 600. The apparatus may include features (e.g., circuitry, logic, one or more controllers, or other functional elements), or instructions (e.g., a non-transitory computer-readable medium storing instructions executable by one or more controllers to control one or more functional elements of the manufacturing system), or any other means or combination thereof for performing the following aspects of the present disclosure:

Aspect 15: A method or apparatus including operations, features, instructions, or any other means or combination thereof for coupling a surface of a first semiconductor component with a first portion of a surface of a second semiconductor component, the first semiconductor component including one or more memory arrays, the second semiconductor component including control circuitry for accessing the one or more memory arrays, and the coupling the surface of the first semiconductor component with the first portion of the surface of the second semiconductor component forming a communicative coupling between the one or more memory arrays and the control circuitry and coupling a surface of a third semiconductor component with a second portion of the surface of the second semiconductor component, without forming a communicative coupling between the third semiconductor component and the second semiconductor component, based at least in part on fusing a first dielectric material at the surface of the third semiconductor component with a second dielectric material at the second portion of the surface of the second semiconductor component.

Aspect 16: The method or apparatus of aspect 15, where the first dielectric material and the second dielectric material include an oxide of silicon, a nitride of silicon, a carbide of silicon, or a combination thereof.

It should be noted that the methods described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 17: An apparatus, including: a first semiconductor component including one or more memory arrays; a second semiconductor component including control circuitry for accessing the one or more memory arrays, where a surface of the first semiconductor component and a first portion of a surface of the second semiconductor component are coupled with a communicative coupling between the one or more memory arrays and the control circuitry; and a third semiconductor component, where a surface of the third semiconductor component and a second portion of the surface of the second semiconductor component are coupled without a communicative coupling between the third semiconductor component and the second semiconductor component, the coupling of the surface of the third semiconductor component and the second portion of the surface of the second semiconductor component based at least in part on a fusion between a first material at the surface of the third semiconductor component and a second material at the second portion of the surface of the second semiconductor component.

Aspect 18: The apparatus of aspect 17, where the first semiconductor component includes: a first semiconductor die including a first subset of the one or more memory arrays; and a second semiconductor die, coupled between the first semiconductor die and the second semiconductor component, including a second subset of the one or more memory arrays.

Aspect 19: The apparatus of any of aspects 17 through 18, where the coupling of the first portion of the surface of the second semiconductor component with the surface of the first semiconductor component includes a fusion between a first electrically conductive material at the surface of the first semiconductor component and a second electrically conductive material at the first portion of the surface of the second semiconductor component.

Aspect 20: The apparatus of aspect 19, where the coupling of the first portion of the surface of the second semiconductor component with the surface of the first semiconductor component includes a fusion between a first dielectric material at the surface of the first semiconductor component and a second dielectric material at the first portion of the surface of the second semiconductor component.

Aspect 21: The apparatus of aspect 20, where at least a portion of the second material and at least a portion of the second dielectric material semiconductor component are contiguous at the surface of the second semiconductor component.

Aspect 22: The apparatus of any of aspects 17 through 21, further including: a mold compound adjacent to the first semiconductor component, adjacent to the third semiconductor component, or between the first semiconductor component and the third semiconductor component, or a combination thereof.

Aspect 23: The apparatus of any of aspects 17 through 22, where the third semiconductor component is formed without circuitry.

Aspect 24: The apparatus of any of aspects 17 through 23, where the first material is formed over a polycrystalline silicon portion of the third semiconductor component.

An apparatus is described. The following provides an overview of aspects of the apparatus as described herein:

Aspect 25: An apparatus formed by a process including: coupling a surface of a first semiconductor component with a first portion of a surface of a second semiconductor component, the first semiconductor component including one or more memory arrays, the second semiconductor component including control circuitry for accessing the one or more memory arrays, and the of coupling the surface of the first semiconductor component with the first portion of the surface of the second semiconductor component forming a communicative coupling between the one or more memory arrays and the control circuitry; and coupling a surface of a third semiconductor component with a second portion of the surface of the second semiconductor component, without forming a communicative coupling between the third semiconductor component and the second semiconductor component, based at least in part on fusing a first material at the surface of the third semiconductor component with a second material at the second portion of the surface of the second semiconductor component.

Aspect 26: The apparatus of aspect 25, formed by the process including: coupling the surface of the first semiconductor component with the first portion of the surface of the second semiconductor component based at least in part on fusing one or more portions a first electrically conductive material at the surface of the first semiconductor component with one or more portions of a second electrically conductive material at the first portion of the surface of the second semiconductor component.

Aspect 27: The apparatus of aspect 26, formed by the process including: coupling the surface of the first semiconductor component with the first portion of the surface of the second semiconductor component based at least in part on fusing one or more portions of a first dielectric material at the surface of the first semiconductor component with one or more portions of a second dielectric material at the first portion of the surface of the second semiconductor component.

Aspect 28: The apparatus of aspect 27, where at least a portion of the second material and at least a portion of the second dielectric material are contiguous at the surface of the second semiconductor component.

An apparatus is described. The following provides an overview of aspects of the apparatus as described herein:

Aspect 29: An apparatus, including: a first semiconductor component including one or more memory arrays; a second semiconductor component including control circuitry for accessing the one or more memory arrays, where a surface of the first semiconductor component and a first portion of a surface of the second semiconductor component are coupled with a communicative coupling between the one or more memory arrays and the control circuitry; and a third semiconductor component, where a surface of the third semiconductor component and a second portion of the surface of the second semiconductor component are coupled without a communicative coupling between the third semiconductor component and the second semiconductor component, the coupling of the surface of the third semiconductor component with the second portion of the surface of the second semiconductor component based at least in part on a fusion between a first dielectric material at the surface of the third semiconductor component and a second dielectric material at the second portion of the surface of the second semiconductor component.

Aspect 30: The apparatus of aspect 29, where the first dielectric material and the second dielectric material include an oxide of silicon, a nitride of silicon, a carbide of silicon, or a combination thereof.

Information and signals described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., an electrically conductive path) between the components that can, at any time, support the flow of signals (e.g., charge, current, voltage) between the components. At any given time, a conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” refers to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components, the controller affects a change that prevents signals from flowing between the components using a conductive path that previously permitted signals to flow.

The description set forth herein, in connection with the appended drawings, describes example configurations and does not represent all the examples that may be implemented or that are within the scope of the claims. The term “exemplary,” used herein means “serving as an example, instance, or illustration,” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. A method, comprising:
coupling a surface of a first semiconductor component with a first portion of a surface of a second semiconductor component, the first semiconductor component comprising one or more memory arrays, the second semiconductor component comprising control circuitry for accessing the one or more memory arrays, and the coupling the surface of the first semiconductor component with the first portion of the surface of the second semiconductor component forming a communicative coupling between the one or more memory arrays and the control circuitry; and
coupling a surface of a third semiconductor component with a second portion of the surface of the second semiconductor component, without forming a communicative coupling between the third semiconductor component and the second semiconductor component, based at least in part on fusing a first material at the surface of the third semiconductor component with a second material at the second portion of the surface of the second semiconductor component.

2. The method of claim 1, wherein coupling the surface of the first semiconductor component with the first portion of the surface of the second semiconductor component comprises:
fusing one or more portions a first electrically conductive material at the surface of the first semiconductor component with one or more portions of a second electrically conductive material at the first portion of the surface of the second semiconductor component.

3. The method of claim 2, wherein coupling the surface of the first semiconductor component with the first portion of the surface of the second semiconductor component comprises:
fusing one or more portions of a first dielectric material at the surface of the first semiconductor component with one or more portions of a second dielectric material at the first portion of the surface of the second semiconductor component.

4. The method of claim 3, wherein at least a portion of the second material and at least a portion of the second dielectric material are contiguous at the surface of the second semiconductor component.

5. The method of claim 1, further comprising:
forming the first material at the surface of the third semiconductor component based at least in part on oxidizing, nitriding, or carbonizing a semiconductor portion of the third semiconductor component, or a combination thereof.

6. The method of claim 1, further comprising:
forming the first material at the surface of the third semiconductor component based at least in part on depositing an oxide material, nitride material, carbide material, or a combination thereof on the surface of the third semiconductor component.

7. The method of claim 1, further comprising:
forming a mold compound adjacent to the first semiconductor component, adjacent to the third semiconductor component, or between the first semiconductor component and the third semiconductor component, or a combination thereof.

8. The method of claim 1, further comprising:
depositing, after coupling the third semiconductor component with the second portion of the surface of the second semiconductor component, the first semiconductor component in an opening through the third semiconductor component; and
coupling the surface of the first semiconductor component with the first portion of the surface of the second semiconductor component with the first semiconductor component in the opening.

9. The method of claim 1, wherein coupling the surface of the third semiconductor component with the second portion of the surface of the second semiconductor component comprises:
depositing the third semiconductor component between a set of multiple first semiconductor components after coupling the set of multiple first semiconductor components with the second semiconductor component.

10. The method of claim 1, wherein the first semiconductor component comprises:
a first semiconductor die including a first subset of the one or more memory arrays; and
a second semiconductor die, coupled with the first semiconductor die, including a second subset of the one or more memory arrays.

11. The method of claim 1, further comprising:
forming a semiconductor assembly comprising the first semiconductor component, a portion of the second semiconductor component, and a portion of the third semiconductor component based at least in part on a separation through the second semiconductor component and the third semiconductor component.

12. The method of claim 1, wherein the second semiconductor component comprises a semiconductor wafer configured for coupling with a plurality of first semiconductor components.

13. The method of claim 1, wherein the third semiconductor component is formed without circuitry.

14. The method of claim 1, wherein the first material is formed over a polycrystalline silicon portion of the third semiconductor component.

15. An apparatus, comprising:
a first semiconductor component including one or more memory arrays;
a second semiconductor component including control circuitry for accessing the one or more memory arrays, wherein a surface of the first semiconductor component and a first portion of a surface of the second semiconductor component are coupled with a communicative coupling between the one or more memory arrays and the control circuitry; and
a third semiconductor component, wherein a surface of the third semiconductor component and a second portion of the surface of the second semiconductor component are coupled without a communicative coupling between the third semiconductor component and the second semiconductor component, the coupling of the surface of the third semiconductor component and the second portion of the surface of the second semiconductor component based at least in part on a fusion between a first material at the surface of the third semiconductor component and a second material at the second portion of the surface of the second semiconductor component.

16. The apparatus of claim 15, wherein the first semiconductor component comprises:
a first semiconductor die including a first subset of the one or more memory arrays; and
a second semiconductor die, coupled between the first semiconductor die and the second semiconductor component, including a second subset of the one or more memory arrays.

17. The apparatus of claim 15, wherein the coupling of the first portion of the surface of the second semiconductor component with the surface of the first semiconductor component comprises a fusion between a first electrically conductive material at the surface of the first semiconductor component and a second electrically conductive material at the first portion of the surface of the second semiconductor component.

18. The apparatus of claim 17, wherein the coupling of the first portion of the surface of the second semiconductor component with the surface of the first semiconductor component comprises a fusion between a first dielectric material at the surface of the first semiconductor component and a second dielectric material at the first portion of the surface of the second semiconductor component.

19. The apparatus of claim 18, wherein at least a portion of the second material and at least a portion of the second dielectric material are contiguous at the surface of the second semiconductor component.

20. The apparatus of claim 15, further comprising:
a mold compound adjacent to the first semiconductor component, adjacent to the third semiconductor component, or between the first semiconductor component and the third semiconductor component, or a combination thereof.

21. The apparatus of claim 15, wherein the third semiconductor component is formed without circuitry.

22. The apparatus of claim 15, wherein the first material is formed over a polycrystalline silicon portion of the third semiconductor component.

23. An apparatus formed by a process comprising:
coupling a surface of a first semiconductor component with a first portion of a surface of a second semiconductor component, the first semiconductor component comprising one or more memory arrays, the second semiconductor component comprising control circuitry for accessing the one or more memory arrays, and the coupling of the surface of the first semiconductor component with the first portion of the surface of the second semiconductor component forming a communicative coupling between the one or more memory arrays and the control circuitry; and
coupling a surface of a third semiconductor component with a second portion of the surface of the second semiconductor component, without forming a communicative coupling between the third semiconductor component and the second semiconductor component, based at least in part on fusing a first material at the surface of the third semiconductor component with a second material at the second portion of the surface of the second semiconductor component.

24. The apparatus of claim 23, formed by the process comprising:
coupling the surface of the first semiconductor component with the first portion of the surface of the second semiconductor component based at least in part on fusing one or more portions a first electrically conductive material at the surface of the first semiconductor component with one or more portions of a second electrically conductive material at the first portion of the surface of the second semiconductor component.

25. The apparatus of claim 24, formed by the process comprising:
coupling the surface of the first semiconductor component with the first portion of the surface of the second semiconductor component based at least in part on fusing one or more portions of a first dielectric material at the surface of the first semiconductor component with one or more portions of a second dielectric material at the first portion of the surface of the second semiconductor component.

26. The apparatus of claim 25, wherein at least a portion of the second material and at least a portion of the second dielectric material component are contiguous at the surface of the second semiconductor component.

27. A method, comprising:
coupling a surface of a first semiconductor component with a first portion of a surface of a second semiconductor component, the first semiconductor component comprising one or more memory arrays, the second semiconductor component comprising control circuitry for accessing the one or more memory arrays, and the coupling the surface of the first semiconductor component with the first portion of the surface of the second semiconductor component forming a communicative coupling between the one or more memory arrays and the control circuitry; and
coupling a surface of a third semiconductor component with a second portion of the surface of the second semiconductor component, without forming a communicative coupling between the third semiconductor component and the second semiconductor component, based at least in part on fusing a first dielectric material at the surface of the third semiconductor component with a second dielectric material at the second portion of the surface of the second semiconductor component.

28. The method of claim 27, wherein the first dielectric material and the second dielectric material comprise an oxide of silicon, a nitride of silicon, a carbide of silicon, or a combination thereof.

29. An apparatus, comprising:
a first semiconductor component including one or more memory arrays;
a second semiconductor component including control circuitry for accessing the one or more memory arrays, wherein a surface of the first semiconductor component and a first portion of a surface of the second semiconductor component are coupled with a communicative coupling between the one or more memory arrays and the control circuitry; and
a third semiconductor component, wherein a surface of the third semiconductor component and a second portion of the surface of the second semiconductor component are coupled without a communicative coupling between the third semiconductor component and the second semiconductor component, the coupling of the surface of the third semiconductor component with the second portion of the surface of the second semiconductor component based at least in part on a fusion between a first dielectric material at the surface of the third semiconductor component and a second dielectric material at the second portion of the surface of the second semiconductor component.

30. The apparatus of claim 29, wherein the first dielectric material and the second dielectric material comprise an oxide of silicon, a nitride of silicon, a carbide of silicon, or a combination thereof.
